(19) United States
(12) Patent Application Publication
(10) Pub. No.: US 2024/0072406 A1
(43) Pub. Date: Feb. 29, 2024

(54) SIGNAL PROCESSING CIRCUIT AND DISTRIBUTION CIRCUIT

(71) Applicant: SONY SEMICONDUCTOR SOLUTIONS CORPORATION, KANAGAWA (JP)

(72) Inventors: TOMOMICHI MURAKAMI, KANAGAWA (JP); EIICHI SANO, KANAGAWA (JP); TAKAHIRO ANDO, KANAGAWA (JP); NORIHIRO MURAYAMA, KANAGAWA (JP)

(21) Appl. No.: 18/261,442

(22) PCT Filed: Dec. 9, 2021
(86) PCT No.: PCT/JP2021/045252

§ 371 Date: Jul. 13, 2023

(30) Foreign Application Priority Data
Jan. 21, 2021 (JP) 2021-008267

(51) Int. Cl. H01P 5/16; H05K 1/02

(52) U.S. Cl. CPC H01P 5/16; H05K 1/0237

(57) ABSTRACT

Provided is a distribution circuit which has good pass characteristic and isolation characteristic over a wide band. A distribution circuit, in which Wilkinson-type distribution circuits configured with a coil, a capacitor, and a resistor are cascaded in two stages between an input terminal and at least three terminals, and a capacitor is connected in parallel with the resistor inserted between the output terminals in the latter-stage Wilkinson-type distribution circuits.

### TECHNICAL FIELD

The present technology relates to a signal processing circuit and a distribution circuit applied to a distribution circuit or a synthesis circuit that distributes or synthesizes a high frequency signal.

### BACKGROUND ART

In digital television broadcasting, tuners compatible with 4K/8K satellite broadcasting are becoming widespread. In a multi-tuner capable of simultaneously receiving a plurality of channels, in order to maintain sensitivity performance equivalent to that of a single tuner, a configuration is common in which an input signal is once amplified by a low noise amplifier (LNA), then distributed by using a distribution circuit, and the signal is input to a tuner configured with an integrated circuit (IC). A video signal is output from the tuner.

As an advanced broadcasting satellite (BS) compatible tuner IC capable of receiving satellite broadcasting of 4K/8K, a tuner IC capable of receiving a band of conventional satellite broadcasting (1032 MHz to 2053 MHz) and a newly added band (2224 MHz to 3224 MHz) with one terminal has been put into practical use. In a case where a signal from an input terminal of a tuner is supplied to a plurality of two or more tuner ICs, for example, three tuner ICs as multi-tuner applications, a distribution circuit that distributes the signal from the input terminal to the three tuner ICs is required. In this case, the distribution circuit has had to cover a wide band of (1032 MHz to 3224 MHz).

A Wilkinson-type distribution circuit has been conventionally known as a distribution circuit. For example, Patent Document 1 describes a Wilkinson-type distribution circuit configured with a lumped constant circuit. The distribution circuit distributes an input signal to three output terminals. Accordingly, the distribution power difference, the frequency characteristic difference, and the phase characteristic difference are prevented from being generated. Patent Document 2 describes a distribution circuit in which Wilkinson-type distribution circuits configured with a lumped constant circuit are cascaded in a plurality of stages to secure reflection characteristic in a wide band.

### CITATION LIST

### Patent Documents

Patent Document 1: Japanese Patent Application Laid-Open No. H02-170625 A
Patent Document 2: Japanese Patent Application Laid-Open No. 2020-136806 A

### SUMMARY OF THE INVENTION

### Problems to be Solved by the Invention

However, the configuration described in Patent Document 1 has the problem that an isolation characteristic of an output port cannot be realized particularly on a low frequency side in a wide band of (1032 MHz to 3224 MHz). Moreover, in a configuration in which two stages of distribution circuits are cascaded as in Patent Document 2, it is not possible to achieve the isolation characteristic of an output port required on a low frequency side as in Patent Document 1. Furthermore, it is considered that the isolation characteristic is improved by further increasing the number of stages, but the number of components increases, the cost increases, and the component mounting area on a substrate also increases.

Therefore, an object of the present technology is to provide a low cost signal processing circuit, and in addition, a distribution circuit that have both a pass characteristic and an isolation characteristic in a wide band and have a reduced number of components.

### Solutions to Problems

The present technology is a signal processing circuit in which a second terminal and a third terminal are connected to a first terminal respectively via two coils, and a resistor and a capacitor are connected in parallel between the second terminal and the third terminal.

In addition, according to the present technology, Wilkinson-type distribution circuits configured with the coil, the capacitor, and the resistor are cascaded in two stages between the first terminal, the second terminal, and the third terminal, and
the capacitor is connected in parallel with the resistor inserted between the second terminal and the third terminal in one of Wilkinson-type distribution circuits.

Moreover, the present technology is a distribution circuit in which Wilkinson-type distribution circuits configured with the coil, the capacitor, and the resistor are cascaded in two stages between an input terminal and at least three output terminals, and
the capacitor is connected in parallel with the resistor inserted between output terminals in a latter-stage Wilkinson-type distribution circuit.

### BRIEF DESCRIPTION OF DRAWINGS

FIG. 1A is a block diagram illustrating a configuration of a conventional single tuner, and FIG. 1B is a block diagram illustrating a configuration of a conventional triple tuner.

FIG. 2 is a block diagram illustrating a configuration of a triple tuner in a case where a band is divided and received.

FIG. 3 is a block diagram illustrating a configuration of a triple tuner in a case where a band is received without being divided.

FIG. 4 is a connection diagram of a conventional distribution circuit.

FIG. 5 is a graph illustrating simulation results of the distribution circuit of FIG. 4.

FIG. 6 is a connection diagram of a conventional distribution circuit.

FIG. 7 is a graph illustrating simulation results of the distribution circuit of FIG. 6.

FIG. 8 is a connection diagram of a distribution circuit in which values of elements of the configuration of FIG. 6 are changed.

FIG. 9 is a graph illustrating simulation results of the distribution circuit of FIG. 8.

FIG. 10 is a connection diagram of a configuration of conventional distribution circuits cascaded.

FIG. 11 is a graph illustrating simulation results of the distribution circuit of FIG. 10.

FIG. 12 is a connection diagram of a first embodiment of the present technology.

FIG. 13 is a graph illustrating simulation results of the distribution circuit of FIG. 12.

FIG. 14 is a plan view of a substrate on which the distribution circuit of FIG. 12 is mounted on one surface.

FIG. 15 is a graph illustrating simulation results of the distribution circuit of FIG. 12.

FIG. 16 is a connection diagram of a modification of an embodiment of the present technology.

FIG. 17 is a plan view of a substrate on which the distribution circuit of FIG. 16 is mounted on one surface.

FIG. 18 is a graph illustrating simulation results of the distribution circuit of FIG. 16.

FIG. 19 is a graph illustrating measurement results of the distribution circuit of FIG. 16.

FIG. 20 is a plan view of one surface of a substrate on which the distribution circuit of FIG. 16 is mounted on both surfaces.

FIG. 21 is a plan view of another surface of a substrate on which the distribution circuit of FIG. 16 is mounted on both surfaces.

FIG. 22 is a connection diagram of a four-way distribution circuit to which the present technology is applied.

FIG. 23 is a connection diagram of a two-way distribution circuit to which the present technology is applied.

FIG. 24 is a connection diagram for explaining that a two-way distribution circuit is configured using a configuration of a three-way distribution circuit.

### MODE FOR CARRYING OUT THE INVENTION

Hereinafter, embodiments and the like of the present technology will be described with reference to the drawings. Note that the embodiment and the like hereinafter described are preferred specific examples of the present technology, and the contents of the present technology are not limited to the embodiment and the like. In addition, in the following description, in order to prevent the illustration from being complicated, only some configurations may be denoted by reference numerals, or some configurations may be illustrated in a simplified manner. Moreover, in the following description, a case where the present technology is applied to a distribution circuit will be described.

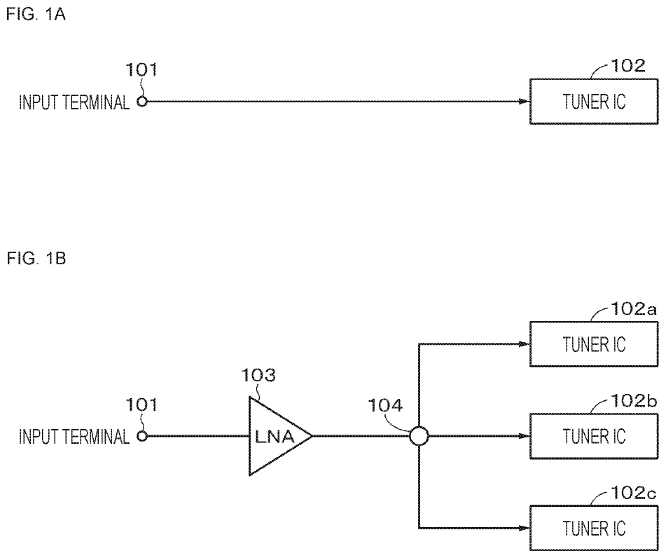

To facilitate understanding of an embodiment, a conventional distribution circuit will be described. In digital television broadcasting, tuner ICs compatible with 4K/8K satellite broadcasting are becoming widespread. In a case of a single tuner, as illustrated in FIG. 1A, a signal from an antenna is input to a tuner IC 102 via an input terminal 101 such as an F connector or an international electrotechnical commission (IEC) connector. A multi-tuner capable of simultaneously receiving a plurality of channels generally has, in order to maintain sensitivity performance equivalent to that of a single tuner, a configuration in which a signal input via an input terminal 101 such as an F connector or an IEC connector is once amplified by an LNA103 as illustrated in FIG. 1B, and then is distributed to tuner ICs 102a, 102b, and 102c by using a distribution circuit 104. The entire configuration may be a tuner module using a mechanical shield or a substrate, or may be onboard using a substrate.

The tuner ICs 102, 102a, 102b, and 102c have the same configuration, include a mixer, a variable gain amplifier, a filter and the like for selecting a specific channel, and output an IF signal. The IF signal is provided to a demodulation module (not illustrated). Tuners having a configuration called an IQ detector or a Zero-IF tuner may be used as the tuner ICs 102, 102a, 102b, and 102c. In this case, an I-axis output and a Q-axis output are output.

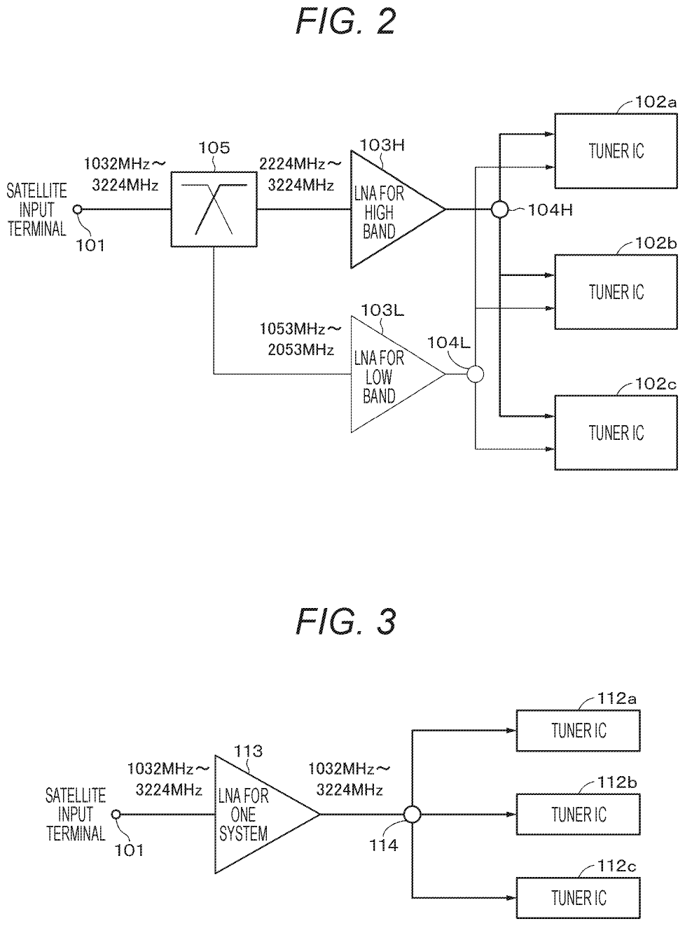

In the conventional advanced BS tuner IC compatible with satellite broadcasting of 4K/8K, there is also a limitation on the frequency characteristic of the LNA and the tuner IC, and as illustrated in FIG. 2, the band of the conventional satellite broadcasting (1032 MHz to 2053 MHz) and the newly added band (2224 MHz to 3224 MHz) are divided into two bands by a branching filter 105, signals of the respective bands are supplied to distribution circuits 104H and 104L via LNAs 103H and 103L, and the signals are input to the two terminals of each band of the tuner ICs 102a, 102b, and 102c by the distribution circuits 104H and 104L.

Recently, since an LNA 113 and tuner ICs 112a, 112b, and 112c capable of supporting these bands with one band have been developed, a branching filter becomes unnecessary, and one distribution circuit 114 is provided as illustrated in FIG. 3. A signal input terminal of the IC is also one terminal. As the distribution circuit 114, a wide band distribution circuit compatible with single system (1032 MHz to 3224 MHz) has been required. The present technology provides a distribution circuit applicable to the wide band distribution circuit 114.

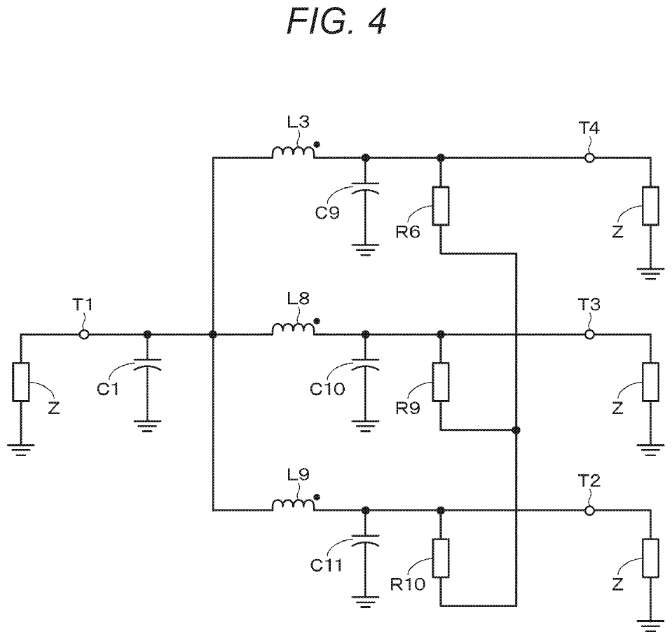

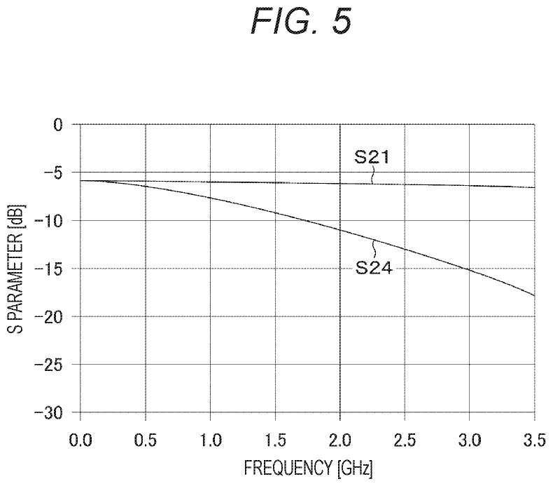

The Wilkinson-type distribution circuit having the configuration of the lumped constant circuit described in Patent Document 1 has the configuration illustrated in FIG. 4. Simulation results of the distribution circuit are illustrated in FIG. 5. An impedance Z (for example, 50Ω or 75Ω) is provided as a termination resistor on an input terminal T1 (first signal terminal). An input capacitor C1 is connected between the input terminal T1 and a ground.

A low-pass filter including a coil L9 and a capacitor C11 is inserted between the input terminal T1 and an output terminal T2 (second terminal). A low-pass filter including a coil L8 and a capacitor C10 is inserted between the input terminal T1 and an output terminal T3 (third terminal). A low-pass filter including a coil L3 and a capacitor C9 is inserted between the input terminal T1 and an output terminal T4 (fourth terminal). Each of the output terminals T2, T3, and T4 is terminated by the impedance Z (for example, 50Ω). The output terminals T2, T3, and T4 are commonly connected via resistors R10, R9, and R6.

In the Wilkinson-type distribution circuit described above, since a signal branched into three signal paths does not return to a branch point on an input side, an impedance at the branch point is maintained. In order to configure a wide band distribution circuit of (1032 MHz to 3224 MHz), the value of each element is selected, for example, as follows.

Z=50[Ω], C1=0.2 [pF], L3, L8, L9=4.7 [nH],

C9, C10, C11=0.2 [pF], R6, R9, R10=220[Ω]

The simulation was performed in steps of 0.01 GHz in a frequency range starting from 0.01 GHz to 3.5 GHz. The results of the simulation are expressed using S-parameters. Among the S parameters, S parameters S21, S31, and S41 representing the pass characteristic from the input terminal T1 to the output terminals T2, T3, and T4 and S parameters S23, S24, and S34 representing the isolation characteristic between the output terminals are important for evaluating the characteristic of the distribution circuit. Here, a lower value of the isolation characteristic is better, and a higher value of the pass characteristic is better. If the isolation characteristic is poor, when a tuner IC performs simultaneous reception in a multi-tuner IC, an interference with another tuner IC may occur, and a reception failure may occur. Furthermore, poor pass characteristic cause sensitivity degradation.

FIG. 5 illustrates the S parameter S21 (pass characteristic from the input terminal T1 to the output terminal T2) and the S parameter 24 (isolation characteristic between the output terminals T2 and T4). In the configuration of FIG. 4, since the values of the corresponding circuit elements included in the three signal paths are equal to each other, the S parameter S31 and the S parameter S41 are similar to the S parameter S21, and the S parameter S23 and the S parameter S34 are similar to the S parameter S24. In the simulation results described below, in a case where only the S parameter 21 and the S parameter S24 are illustrated, it means that other S parameters are similar. From the simulation results of FIG. 5, it can be seen that the pass characteristic is good, but the isolation characteristic in the low frequency range is insufficient. For example, an isolation characteristic of 15 dB at 1 GHz (target value) has not been achieved.

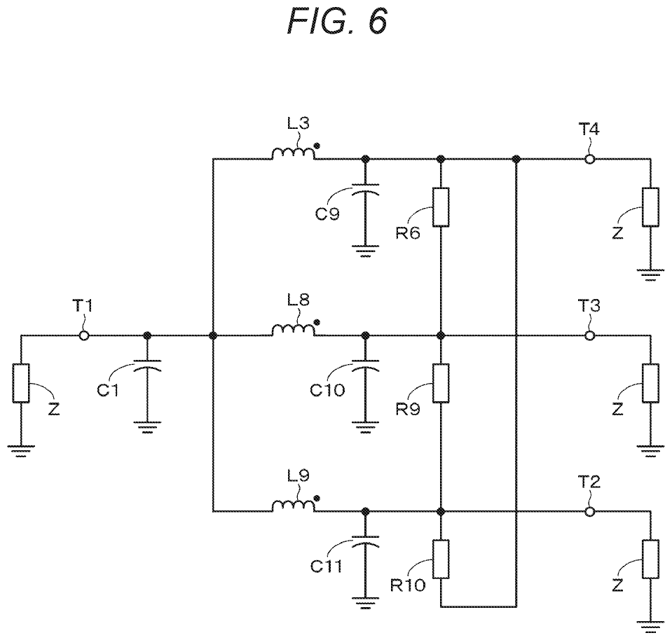

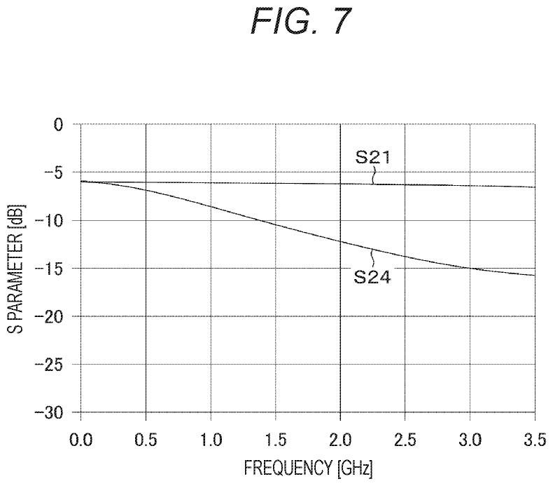

FIG. 6 illustrates a circuit configuration obtained by modifying the connection of the resistors R6, R9, and R10 in the circuit configuration of FIG. 4 using star-delta conversion. Simulation results of the distribution circuit of FIG. 6 are illustrated in FIG. 7. The value of each element is the same as the value of the element in FIG. 4. The simulation results are almost the same as the simulation results of FIG. 5, and indicate that the isolation characteristic in the low frequency range is insufficient.

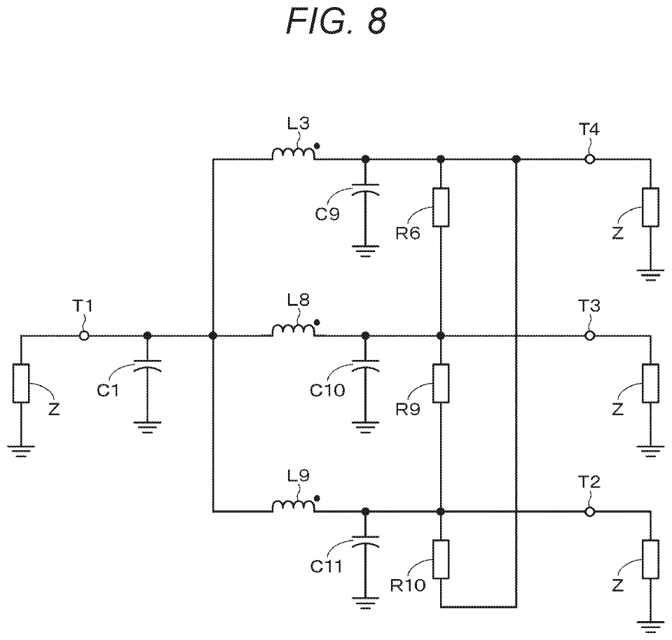

In order to improve the isolation characteristic, there is a method available for lowering a cutoff frequency of a low-pass filter type distribution circuit. FIG. 8 illustrates a configuration of a distribution circuit adopting such a method. Although the connection is the same as that of the distribution circuit of FIG. 6, each element has the following value.

Z=50[Ω], C1=0.2 [pF], L3, L8, L9=6.8 [nH],

C9, C10, C11=0.2 [pF], R6, R9, R10=220[Ω]

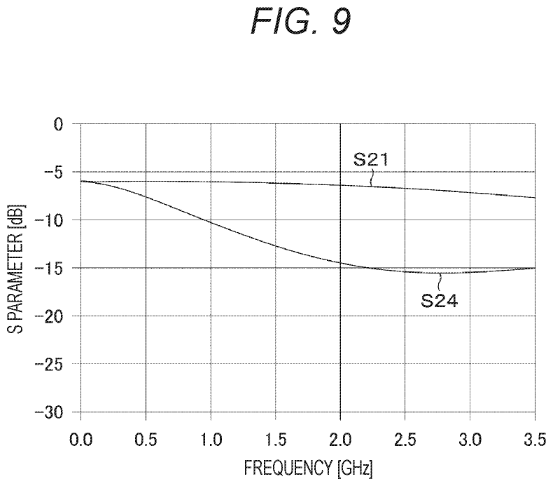

The value (4.7 [nH]) of the coils L3, L8, and L9 in the configurations of FIGS. 4 and 6 is changed to 6.8 [nH]. The simulation result of FIG. 9 indicates that the isolation characteristic has been improved, but the isolation characteristic is still insufficient, and the pass characteristic on the high frequency side has been slightly deteriorated. That is, there is a trade-off between the isolation characteristic and the pass characteristic, and a desired wide band distribution circuit cannot be configured in the circuit configuration of FIG. 8.

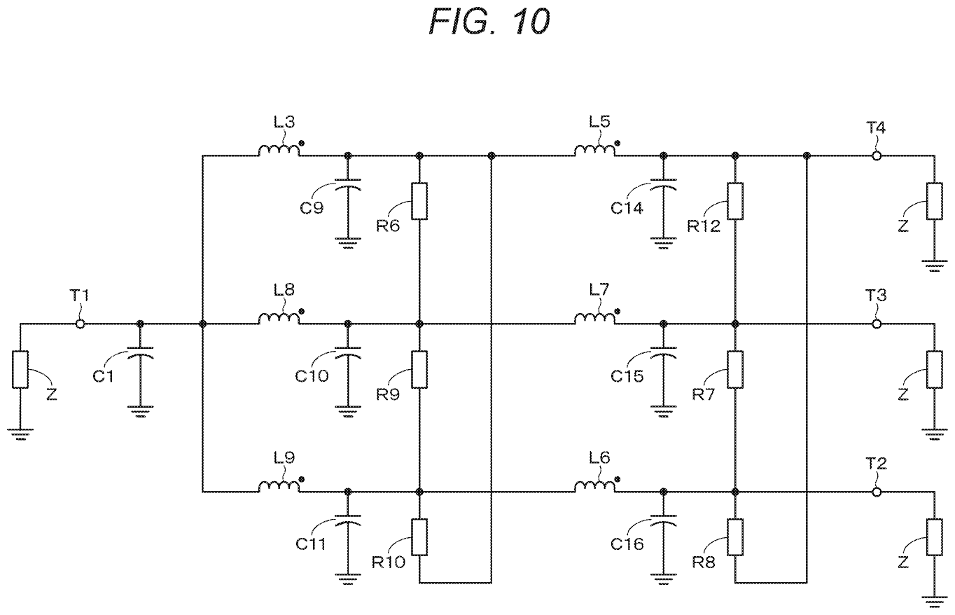

In order to further improve the characteristic, as illustrated in FIG. 10, a configuration in which the Wilkinson-type distribution circuits illustrated in FIG. 6 are cascaded in two stages is considered. The second-stage Wilkinson-type distribution circuit has a circuit configuration similar to that of the first-stage. The low-pass filter including the coil L9 and the capacitor C11 and a low-pass filter including a coil L6 and a capacitor C16 are cascaded between an input terminal T1 and an output terminal T2 (second terminal). The low-pass filter including the coil L8 and the capacitor C10 and a low-pass filter including a coil L7 and a capacitor C15 are cascaded between the input terminal T1 and an output terminal T3 (third terminal). The low-pass filter including the coil L3 and the capacitor C9 and a low-pass filter including a coil L5 and a capacitor C14 are cascaded between the input terminal T1 and an output terminal T4 (fourth terminal).

In the first-stage Wilkinson-type distribution circuit, an output of the low-pass filter including the coil L9 and the capacitor C11 and an output of the low-pass filter including the coil L8 and the capacitor C10 are connected via a resistor R9. The output of the low-pass filter including the coil L9 and the capacitor C11 and an output of the low-pass filter including the coil L3 and the capacitor C9 are connected via a resistor R10. The output of the low-pass filter including the coil L8 and the capacitor C10 and the output of the low-pass filter including the coil L3 and the capacitor C9 are connected via a resistor R6. Moreover, a resistor R7 and a resistor R8 are inserted between the output terminal T2, the output terminals T3, and the output terminal T4, respectively, and a resistor R12 is inserted between the output terminal T3 and the output terminal T4. The resistor R8, the resistor R7, and the resistor R12 function as resistors for matching, which improves the isolation characteristic.

An example of a value of each element in the configuration of FIG. 10 will be described below.

Z=50[Ω], C1=0.2 [pF], L3, L8, L9=4.7 [nH],

C9, C10, C11=0.2 [pF], R6, R9, R10=220[Ω]

L5, L7, L6=3.9 [nH],

C14, C15, C16=0.2 [pF], R12, R7, R8=330[Ω]

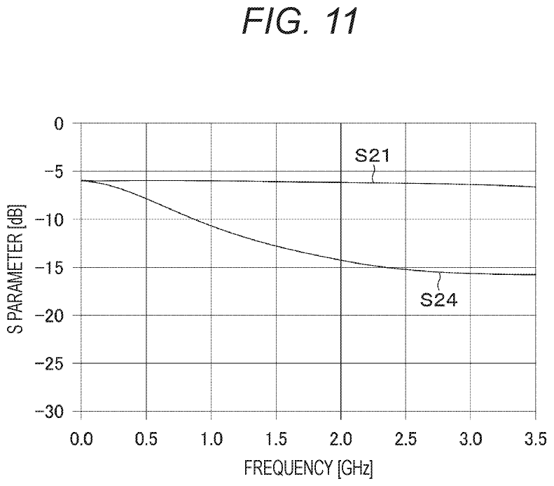

The value of each element is not completely the same between the first-stage Wilkinson-type distribution circuit and the second-stage Wilkinson-type distribution circuit, and is an adjusted value. Simulation results of the distribution circuit of the configuration of FIG. 10 are illustrated in FIG. 11. Although the isolation characteristic has been considerably improved, the target value (15 dB at 1 GHz) for the isolation characteristic on the low frequency side has not been achieved.

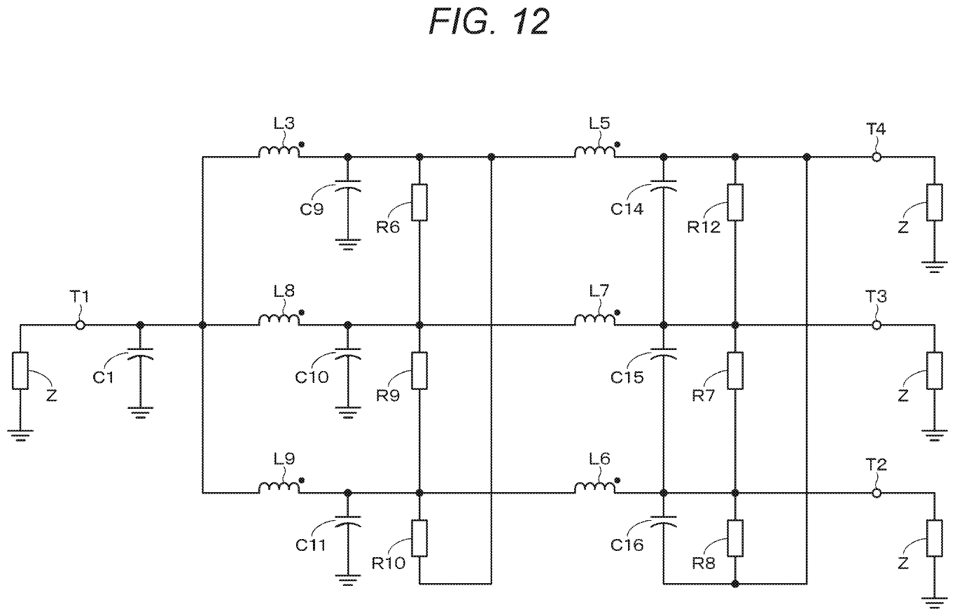

The present technology proposes a distribution circuit that solves the above-described problem that the isolation characteristic on the low frequency side become insufficient. FIG. 12 illustrates a configuration of an embodiment in which the present technology is applied to a distribution circuit that distributes input signals into three.

The impedance Z (for example, 50Ω) is connected as a termination resistor to the input terminal (first terminal) T1, the output terminal (second terminal) T2, the output terminal (third terminal) T3, and the output terminal T4 (fourth terminal). The input capacitor C1 is connected between the input terminal T1 and the ground. An input signal from the input terminal T1 is divided into three signal systems corresponding to the output terminals T2, T3, and T4, respectively.

The low-pass filter including the coil L9 and the capacitor C11, and the coil L6 are cascaded between the input terminal T1 and the output terminal T2. The low-pass filter including the coil L8 and the capacitor C10, and the coil L7 are cascaded between the input terminal T1 and the output terminal T3. The low-pass filter including the coil L3 and the capacitor C9, and the coil L5 are cascaded between the input terminal T1 and the output terminal T4.

The capacitor C15 and the resistor R7 are connected in parallel between the connection point of the coil L6 and the output terminal T2 and the connection point of the coil L7 and the output terminal T3. The capacitor C14 and the resistor R12 are connected in parallel between the connection point of the coil L7 and the output terminal T3 and the connection point of the coil L5 and the output terminal T4. The capacitor C16 and the resistor R8 are connected in parallel between the connection point of the coil L5 and the output terminal T4 and the connection point of the coil L6 and the output terminal T2.

The coils L9, L8, and L3, the capacitors C11, C10, and C9, and the resistors R10, R9, and R6 configure the first-stage Wilkinson-type distribution circuit. The coils L6, L7, and L5, the capacitors C16, C15, and C14, and the resistors R8, R7, and R12 configure the second-stage Wilkinson-type distribution circuit.

An example of a value of each element in FIG. 12 will be described below.

Z=50[Ω], C1=0.2 [pF], L3, L8, L9=4.7 [nH],

C9, C10, C11=0.2 [pF], R6, R9, R10=220[Ω]

L5, L7, L6=3.9 [nH],

C14, C15, C16=0.2 [pF], R12, R7, R8=330[Ω]

In the circuit configuration illustrated in FIG. 12, the capacitor C15, the capacitor C14, and the capacitor C16 are connected in parallel to the resistor R7, the resistor R12, and the resistor R8 for isolation, respectively, inserted between the output terminals T2 and T3, between the output terminals T3 and T4, and between the output terminals T4 and T2. Isolation poles are formed by these capacitors (0.2 [pF]) and the coils L6, L7, and L5 (3.9 [nH]) connected to a preceding stage thereof, and as a result, the isolation characteristic on the low frequency side can be improved. Furthermore, the isolation characteristic can be improved by shifting the values of the elements of the first-stage and the second-stage.

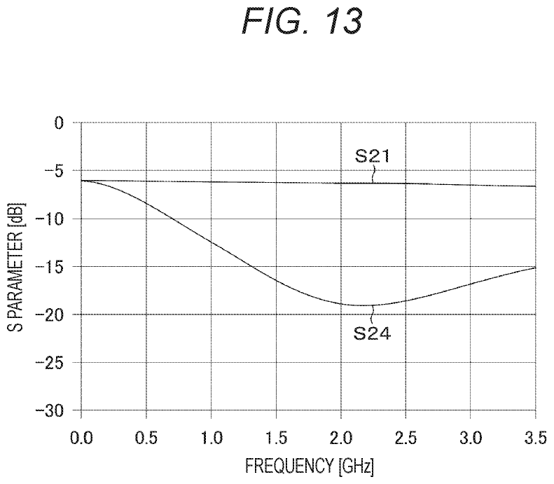

Simulation results of the distribution circuit of the configuration of FIG. 12 are illustrated in FIG. 13. In the simulation results, the target value (15 dB at 1 GHz) regarding the isolation characteristic on the low frequency side has not been slightly achieved, but as will be described later, this target has been achieved with actual measured values.

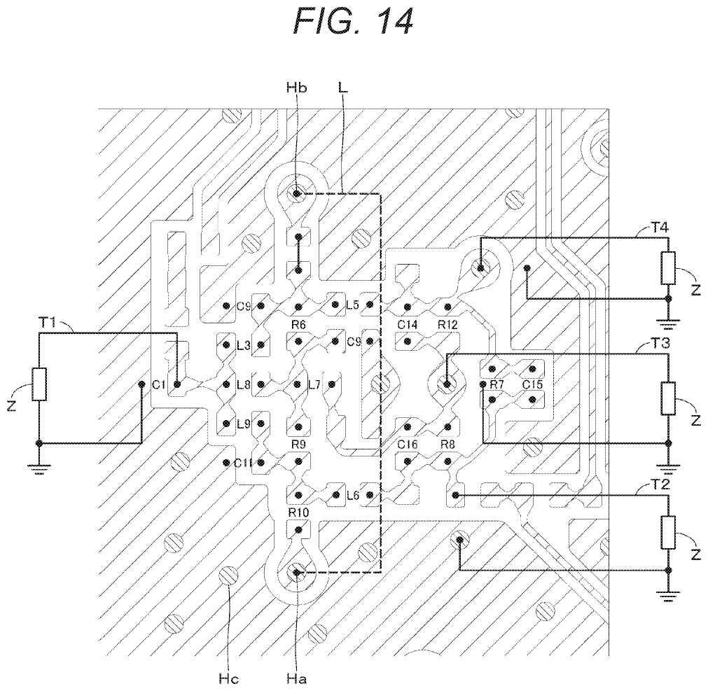

FIG. 14 illustrates an example of a substrate on which the circuit illustrated in FIG. 12 is mounted. In this example, elements are mounted on one surface (appropriately referred to as surface A) of the substrate except for a signal line that connects one end of the resistor R10 to a connection point of the coil L3 and the coil L5. Single-sided mounting can reduce manufacturing costs as compared to double-sided mounting. However, in the circuit configuration of FIG. 12, since the signal line connecting one end of the resistor R10 to the connection point of the coil L3 and the coil L5 crosses other signal lines, it is difficult to wire the signal line to the A surface of the substrate, and the signal line is wired to the other surface (appropriately referred to as surface B) as indicated by a broken line in FIG. 14. Since this wiring is relatively long, it cannot be ignored for a high frequency signal. That is, the wiring becomes a stub with respect to the signal line connecting the resistors R10, R9, and R6. As a circuit diagram, a wiring portion L between R10 and R6 in FIG. 12 corresponds to a stub. Furthermore, in FIG. 14, a portion having • at a center of a shaded o indicates a through hole of a signal wiring, and a portion having no • at the center of the shaded o indicates a through hole connected to GND of another layer of the substrate. The wiring portion L is formed between through holes Ha and Hb. For example, Hc is a through hole connected to GND. A layer configuration of the substrate may be a double-sided substrate, a four-layer substrate, or another layer configuration.

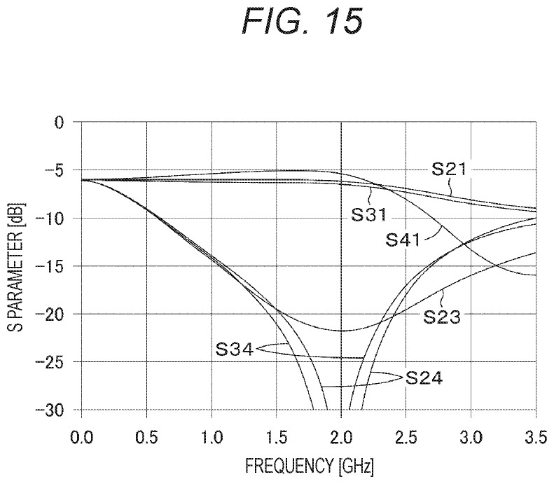

Simulation results of the substrate (FIG. 14) on which a stub is generated are illustrated in FIG. 15. As illustrated in FIG. 14, there is a resistor only on the output terminal T2 side, and from the simulation results, the pass characteristic on the higher frequency side than 2 GHz is significantly deteriorated (particularly, pass characteristic S41 related to the output terminal T4). This is because, since there is no resistor on the output terminal T4 side, when a stub is formed on the surface of the substrate B, a phase-shifted signal that has passed through the path returns to the output terminal T4 and cancels the desired signal, so that the pass characteristic is greatly deteriorated on the high-frequency side with respect to the output terminal T4.

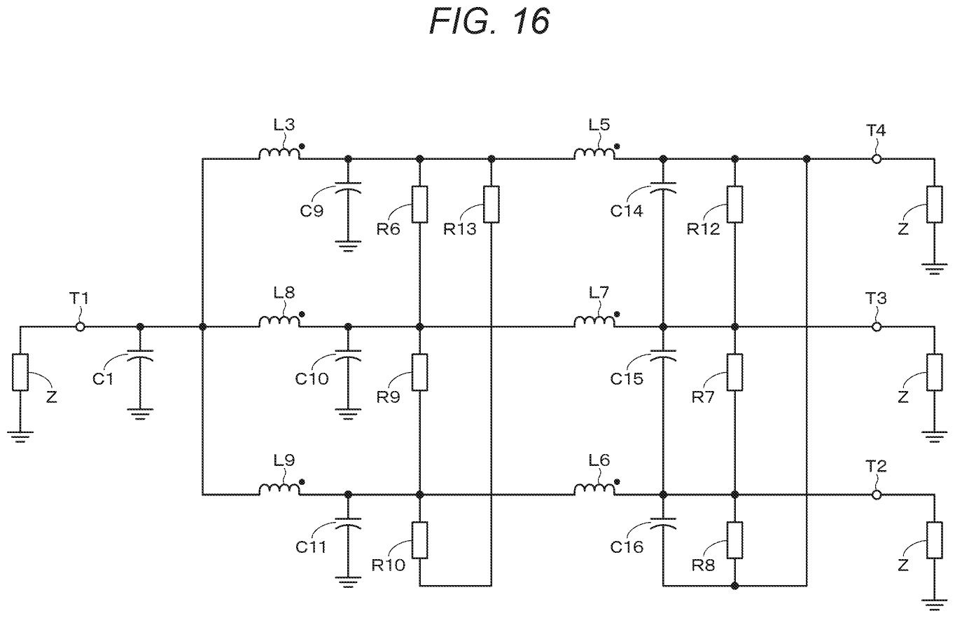

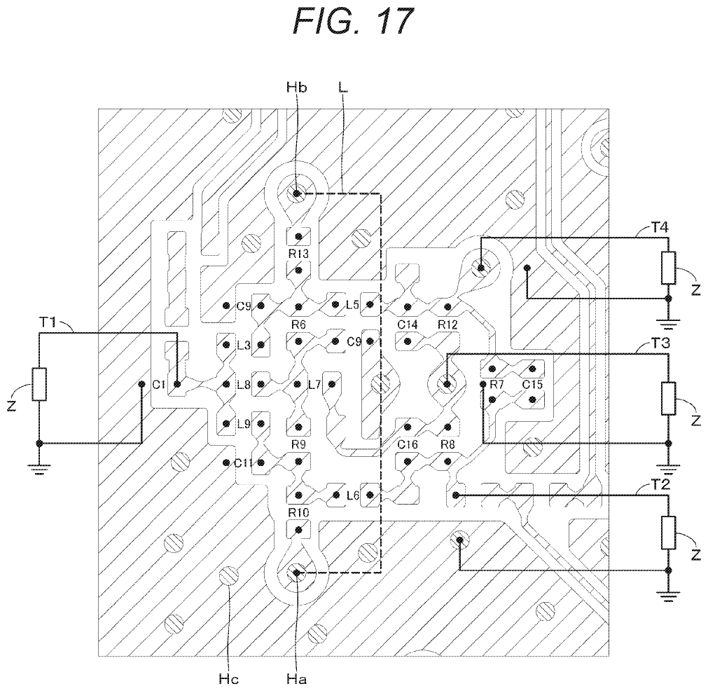

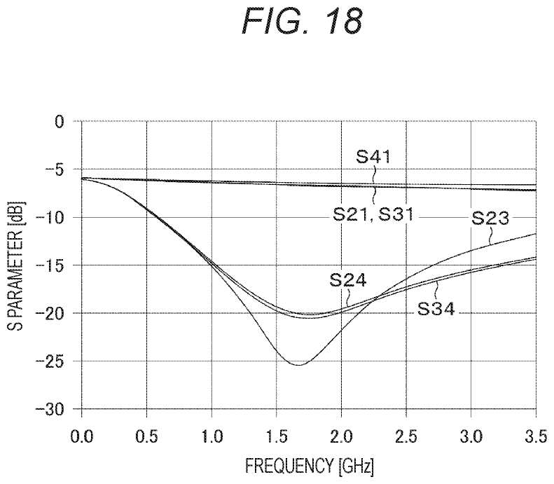

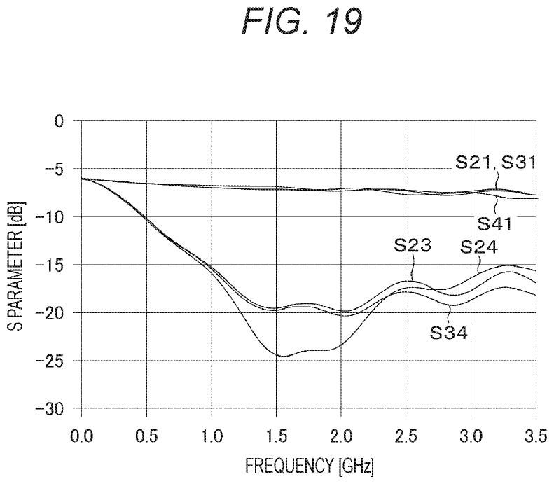

In order to solve this problem, as illustrated in FIG. 16, a connection point of the coil L9 and the coil L6 (the output of the low-pass filter including the coil L9 and the capacitor C11) is connected to the connection point of the coil L3 and the coil L5 (the output of the low-pass filter including the coil L3 and the capacitor C9) via the resistor R10 and a resistor R13. An example of mounting the substrate in this case is illustrated in FIG. 17. By adding the resistor R13, as can be seen from simulation results illustrated in FIG. 18, an influence of the stub can be suppressed. That is, it is possible to prevent the pass characteristic S41 related to the output terminal T4 from attenuating on the high frequency side. Moreover, characteristic obtained by actually prototyping and evaluating (measuring) a substrate is illustrated in FIG. 19. It was possible to obtain characteristic substantially matching the simulation results, which achieved a target isolation characteristic of 15 dB.

An example of a value of each element in FIG. 16 will be described below.

Z=50[Ω], C1=0.2 [pF], L3, L8, L9=4.7 [nH],

C9, C10, C11=0.2 [pF], R6, R9, =220[Ω]

R10, R13=560[Ω]

L5, L7, L6=3.9 [nH],

C14, C15, C16=0.2 [pF], R12, R7, R8=330[Ω]

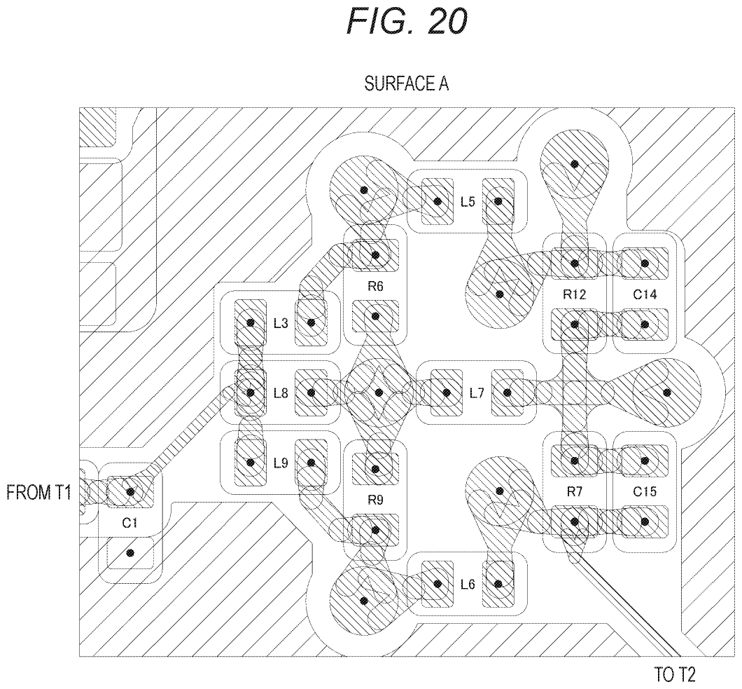

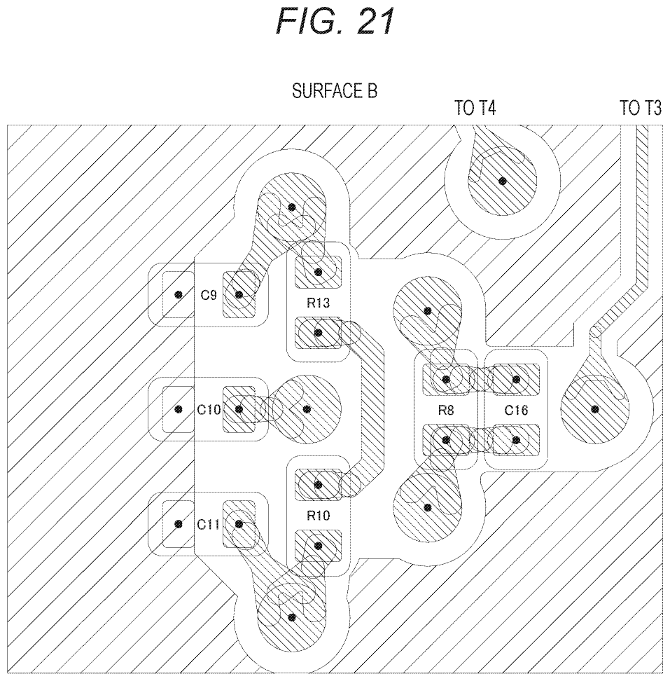

In the present technology, the distribution circuit may be mounted using both surfaces (surface A and surface B) of the substrate. FIGS. 20 and 21 illustrate examples in which the circuit having the configuration illustrated in FIG. 16 is mounted on both surfaces of the substrate. FIG. 20 illustrates a pattern of the surface A, and FIG. 21 illustrates a pattern of the surface B. The patterns of the surface A and the surface B are connected via through holes. In the case of double-sided mounting, when the isolation resistors R10, R9, R6, and R13 are inserted between output terminals, deterioration of the pass characteristic can be prevented by arranging the isolation resistors in the vicinity of each signal line (wiring pattern). Also in this case, as a layer configuration of substrate, the layer configuration of substrate may be a double-sided substrate, a four-layer substrate, or another layer configuration.

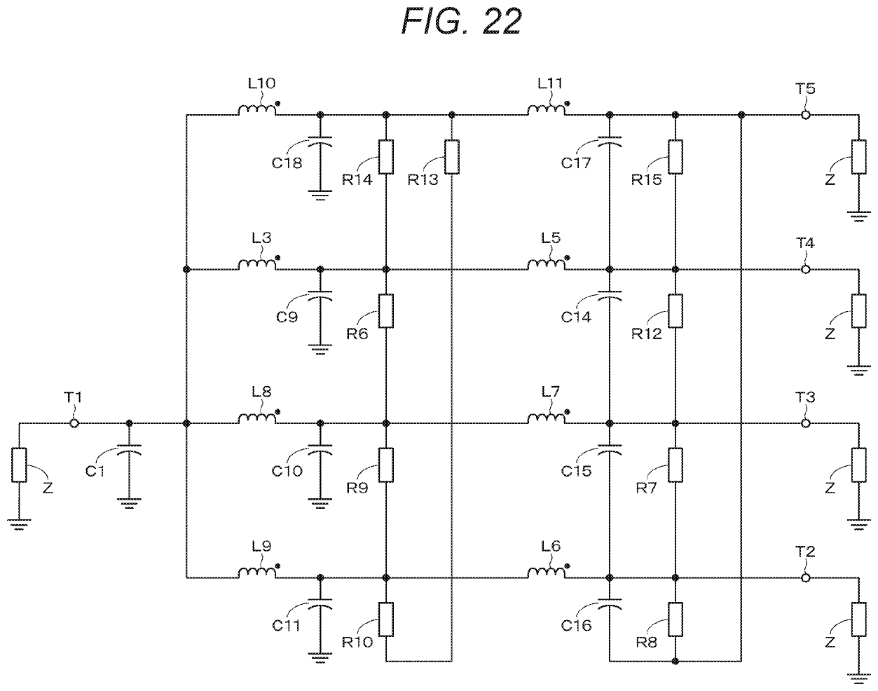

The above description is for a configuration in which the input signal is distributed to three outputs, but it may be not only three-way distribution but also another distribution in the present technology. For example, FIG. 22 illustrates a configuration in which an input signal is distributed to four output terminals T2, T3, T4, and T5. A first-stage Wilkinson-type distribution circuit (coil L10, capacitor C18, resistor R14) is added to the configuration of FIG. 16 described above, and a second-stage Wilkinson-type distribution circuit including a coil L11, a capacitor C17, and a resistor R15 is added.

An example of a value of each element in FIG. 22 will be described below.

Z=50[Ω], C1=0.2 [pF], L3, L8, L9, L10=4.7 [nH], C9,

C10, C11, C18=0.2 [pF], R9, R6, R14=220[Ω]

R10, R13=560[Ω]

L5, L7, L6, L11=3.9 [nH],

C17, C14, C15, C16, =0.2 [pF], R15, R12, R7, R8=330[Ω]

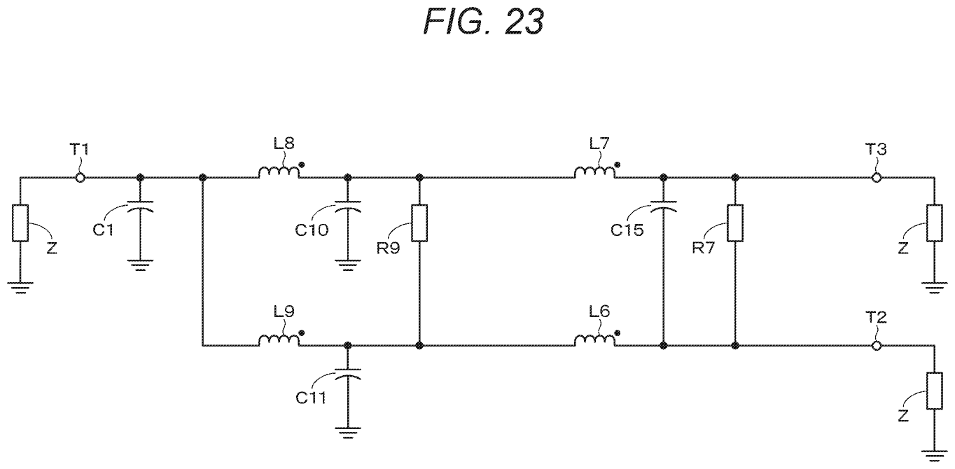

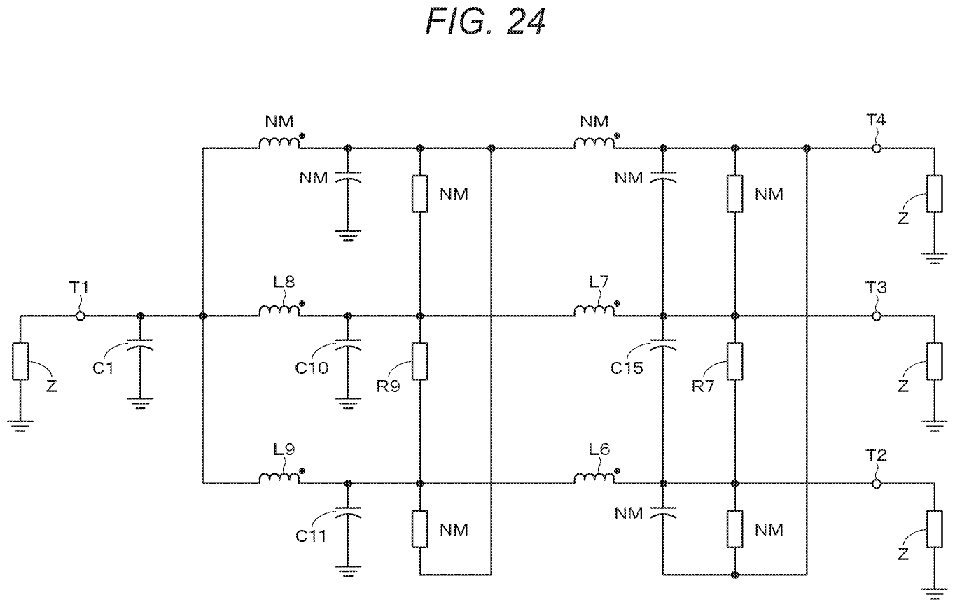

FIG. 23 illustrates a configuration example of a two-way distribution circuit. A circuit related to the input terminal T1 and the output terminals T2 and T3 is provided. Moreover, as illustrated in FIG. 24, a configuration of a three-way distribution circuit is laid out on the substrate. Here, NM (No mount) indicates that no element is mounted. By not mounting the element, a two-way distribution circuit can be realized. Furthermore, a configuration of one system that does not perform distribution can be realized. Therefore, it is possible to realize various configurations only by changing elements or constants to be mounted on the same substrate, to achieve commonality of the substrates, and to achieve cost reduction.

An example of a value of each element in FIG. 23 will be described below.

Z=50[Ω], C1=0.2 [pF], L8, L9=4.7 [nH],

C10, C11=0.2 [pF], R9=220[Ω]

L7, L6=3.9 [nH],

C15=0.2 [pF], R7=330[Ω]

As can be seen from the description of the embodiments described above, the present technology can realize a distribution circuit having both pass characteristic and isolation characteristic in a wide band (1032 MHz to 3224 MHz). Furthermore, the circuit of the present technology can be mounted on a single-sided substrate. Moreover, the present technology can configure a distribution circuit of a desired distribution number such as two-way distribution, three-way distribution, or four-way distribution, and has a configuration excellent in versatility.

Although the embodiments of the present technology have been specifically described above, it is not limited to the above-described embodiment, and various modifications based on the technical idea of the present technology are possible. For example, the present technology is not limited to the band of (1032 MHz to 3224 MHz), and the present technology can be applied to other bands by changing values of the elements. Moreover, the present technology can be used not only in broadcasting but also in the field of communication. In addition, a synthesis circuit may be configured by switching an input and an output such that the input terminal is used as the output terminal and the output terminal is used as the input terminal.

The configurations, methods, steps, shapes, materials, numerical values, and the like described in the above embodiments are merely examples, and different configurations, methods, steps, shapes, materials, numerical values, and the like may be used as necessary. The above embodiments and modifications can be appropriately combined.

The present technology may have the following configurations.

(1)

A signal processing circuit in which a second terminal and a third terminal are connected to a first terminal respectively via two coils, and a resistor and a capacitor are connected in parallel between the second terminal and the third terminal.

(2)

The signal processing circuit according to (1), in which a signal is input to the first terminal, and signals are output from the second terminal and the third terminal.

(3)

The signal processing circuit according to (1), in which a signal is input to the second terminal and the third terminal, and a signal is output from the first terminal.

(4)

A signal processing circuit, in which Wilkinson-type distribution circuits configured with a coil, a capacitor, and a resistor are cascaded in two stages between a first terminal, a second terminal, and a third terminal, and
a capacitor is connected in parallel with the resistor inserted between the second terminal and the third terminal in one of the Wilkinson-type distribution circuits.
   (5)

The signal processing circuit according to (4), in which a signal is input to the first terminal, and signals are output from the second terminal and the third terminal.

(6)

The signal processing circuit according to (4), in which a signal is input to the second terminal and the third terminal, and a signal is output from the first terminal.

(7)

A distribution circuit, in which Wilkinson-type distribution circuits configured with a coil, a capacitor, and a resistor are cascaded in two stages between an input terminal and at least three terminals, and
a capacitor is connected in parallel with the resistor inserted between the output terminals in the latter-stage Wilkinson-type distribution circuits.
   (8)

The distribution circuit according to (7), in which a resistor is connected in series with one resistor among a plurality of resistors inserted between signal systems corresponding to the plurality of output terminals in the former-stage Wilkinson-type distribution circuit.

(9)

The distribution circuit according to (8), in which the resistor is connected in series with a resistor inserted between signal systems at distant positions in a pattern mounted on one surface of the substrate.

(10)

(7) A distribution circuit configured to obtain less output by not mounting elements included in one or a plurality of signal systems on a substrate on which a pattern is formed so that the distribution circuit of 7 can be mounted.

### REFERENCE SIGNS LIST

T1 Input terminal
T2, T3, T4 Output terminal
C1 Input capacitor
101 Input terminal of signal from antenna
102, 102a, 102b, 102c Tuner IC
104, 114 Distribution circuit

1. A signal processing circuit, wherein a second terminal and a third terminal are connected to a first terminal respectively via two coils, and a resistor and a capacitor are connected in parallel between the second terminal and the third terminal.

2. The signal processing circuit according to claim 1, wherein a signal is input to the first terminal, and a signal is output from the second terminal and the third terminal.

3. The signal processing circuit according to claim 1, wherein a signal is input to the second terminal and the third terminal, and a signal is output from the first terminal.

4. A signal processing circuit, wherein Wilkinson-type distribution circuits configured with a coil, a capacitor, and a resistor are cascaded in two stages between a first terminal, a second terminal, and a third terminal, and
a capacitor is connected in parallel with the resistor inserted between the second terminal and the third terminal in one of the Wilkinson-type distribution circuits.

5. The signal processing circuit according to claim 4, wherein a signal is input to the first terminal, and a signal is output from the second terminal and the third terminal.

6. The signal processing circuit according to claim 4, wherein a signal is input to the second terminal and the third terminal, and a signal is output from the first terminal.

7. A distribution circuit, wherein Wilkinson-type distribution circuits configured with a coil, a capacitor, and a resistor are cascaded in two stages between an input terminal and at least three terminals, and
a capacitor is connected in parallel with the resistor inserted between the output terminals in the latter-stage Wilkinson-type distribution circuits.

8. The distribution circuit according to claim 7, wherein a resistor is connected in series with one resistor among a plurality of resistors inserted between signal systems corresponding to the plurality of output terminals in the former-stage Wilkinson-type distribution circuit.

9. The distribution circuit according to claim 8, wherein the resistor is connected in series with a resistor inserted between signal systems at distant positions in a pattern mounted on one surface of the substrate.

10. A distribution circuit configured to obtain less output by not mounting elements included in one or a plurality of signal systems on a substrate on which a pattern is formed so that the distribution circuit according to claim 7 can be mounted.
